(19) United States
(12) Patent Application Publication
(10) Pub. No.: US 2014/0106268 A1
(43) Pub. Date: Apr. 17, 2014

(54) IRRADIATION APPARATUS, DRAWING APPARATUS, AND METHOD OF MANUFACTURING ARTICLE

(71) Applicant: CANON KABUSHIKI KAISHA, Tokyo (JP)

(72) Inventor: Nobuo Imaoka, Utsunomiya-shi (JP)

(73) Assignee: CANON KABUSHIKI KAISHA, Tokyo (JP)

(21) Appl. No.: 14/043,253

(22) Filed: Oct. 1, 2013

(30) Foreign Application Priority Data
Oct. 16, 2012 (JP) 2012-229244

(51) Int. Cl. H01J 37/317

(52) U.S. Cl. CPC H01J 37/3174
USPC 430/30; 250/397

(57) ABSTRACT

The present invention provides an irradiation apparatus which irradiates an object with a charged particle beam, the apparatus including a first charged particle optical system including a charged particle source, a second charged particle optical system into which a charged particle beam is incident from the first charged particle optical system, a detector configured to be moved and to detect a charged particle beam from the first charged particle optical system, and a regulator configured to regulate relative positions between the first charged particle optical system and the second charged particle optical system based on an output from the detector disposed between the first charged particle optical system and the second charged particle optical system.

### BACKGROUND OF THE INVENTION

1. Field of the Invention

The present invention relates to an irradiation apparatus, a drawing apparatus, and a method of manufacturing an article.

2. Description of the Related Art

A charged particle beam drawing apparatus which draws on a substrate with a charged particle beam (electron beam) is known as an apparatus which is used in a manufacturing process (lithography process) for a semiconductor device.

A drawing apparatus needs to exchange a charged particle source, which generates a charged particle beam, in accordance with the operating time and use frequency because the charged particle source is a consumable article. In addition, in order to maintain the position, dimension accuracy, and the like of the pattern drawn on a substrate, it is necessary to maintain the charged particle source at the time of exchange of the charged particle source or periodically. Japanese Patent Laid-Open Nos. 1-208456 and 2005-026112 have proposed a technique associated with the exchange and maintenance of such a charged particle source.

Japanese Patent Laid-Open No. 1-208456 discloses a technique of accommodating a charged particle source (electron gun) for exchange in a sub-vacuum chamber before the exchange of the charged particle source and shortening the time to evacuate the space for accommodating the charged particle source after the exchange by evacuating the sub-vacuum chamber in advance. Japanese Patent Laid-Open No. 2005-026112 discloses a technique of performing maintenance such as bakeout and conditioning processing by applying a high voltage to each electrode of a charged particle source under a vacuum environment after the exchange of a charged particle source. In this case, bakeout is the processing of removing (eliminating) impurities adhering to a charged particle source (electrode), and conditioning processing is processing for stabilizing a charged particle source.

Upon exchanging a charged particle source, a drawing apparatus needs to position a charged particle optical system on the front stage including the charged particle source with respect to a charged particle optical system on the subsequent stage of the charged particle optical system. More specifically, it is necessary to align the axis (optical axis) of the charged particle optical system on the front stage with the axis of the charged particle optical system on the subsequent stage. It is therefore necessary to perform optical axis alignment for a charged particle source (that is, to detect the position of a charged particle beam emerging from the charged particle optical system on the front stage). However, a conventional drawing apparatus has no function of performing optical axis alignment for a charged particle source on the apparatus, and hence it can take much time to align the axis of the charged particle optical system on the front stage with the axis of the charged particle optical system on the subsequent stage. This is because the position of the charged particle source can shift during transportation, or the location of the charged particle source can shift when being incorporated in a drawing apparatus.

### SUMMARY OF THE INVENTION

The present invention provides, for example, an irradiation apparatus advantageous in alignment of a charged particle optical system including a charged particle source.

According to one aspect of the present invention, there is provided an irradiation apparatus which irradiates an object with a charged particle beam, the apparatus including a first charged particle optical system including a charged particle source, a second charged particle optical system into which a charged particle beam is incident from the first charged particle optical system, a detector configured to be moved and to detect a charged particle beam from the first charged particle optical system, and a regulator configured to regulate relative positions between the first charged particle optical system and the second charged particle optical system based on an output from the detector disposed between the first charged particle optical system and the second charged particle optical system.

Further aspects of the present invention will become apparent from the following description of exemplary embodiments with reference to the attached drawings.

### BRIEF DESCRIPTION OF THE DRAWINGS

FIG. 1 is a schematic view showing the arrangement of a drawing apparatus according to an aspect of the present invention.

FIG. 2 is a schematic view showing the arrangement of the drawing apparatus according to another aspect of the present invention.

FIG. 3 is a flowchart for explaining exchange processing for a charged particle source in the drawing apparatus shown in FIG. 1.

FIG. 4 is a schematic view showing a state in which the position of a charged particle beam emerging from the first charged particle optical system in step S629 shown in FIG. 3.

### DESCRIPTION OF THE EMBODIMENTS

Preferred embodiments of the present invention will be described below with reference to the accompanying drawings. Note that the same reference numerals denote the same members throughout the drawings, and a repetitive description thereof will not be given.

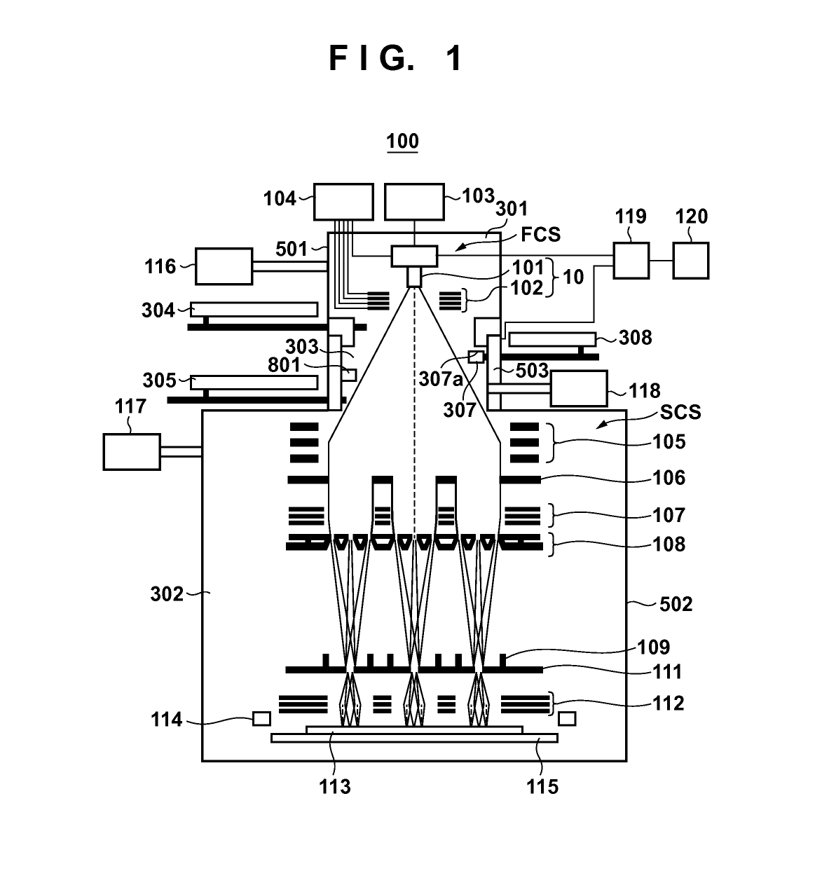

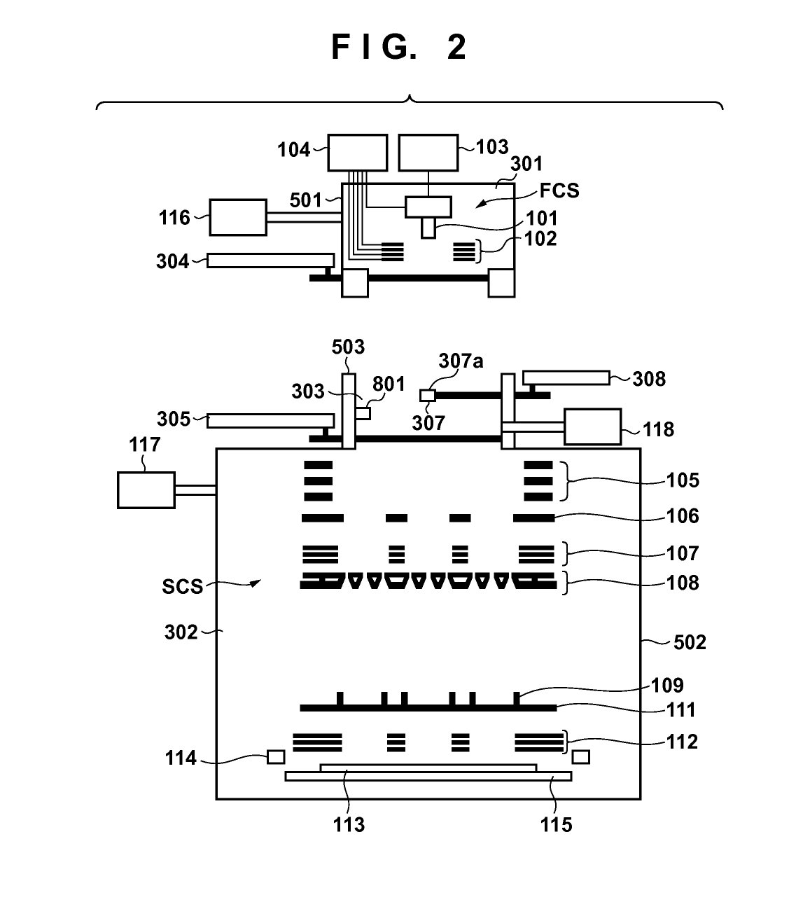

FIGS. 1 and 2 are schematic views showing the arrangement of a drawing apparatus 100 according to aspects of the present invention. The drawing apparatus 100 is a lithography apparatus which draws on a substrate with a charged particle beam (electron beam), that is, draws a pattern on the substrate by using a charged particle beam. In this embodiment, the drawing apparatus 100 individually includes a projection system. That is, this apparatus is implemented as a multi-column type drawing apparatus.

The drawing apparatus 100 includes a charged particle source 10, a heating mechanism 103, a voltage applying unit 104, a collimator lens 105, an aperture array 106, a condenser lens array 107, an aperture array 108, and a blanker array 109. The drawing apparatus 100 includes a blanking aperture 111, a condenser lens array 112, a deflector 114, a substrate stage 115, vacuum pump mechanisms 116, 117, and 118, a regulation unit 119, and a control unit 120. The drawing apparatus 100 further includes valve mechanisms 304 and 305, a detector 307, a moving unit 308, a first chamber 501, a second chamber 502, and a third chamber 503.

The charged particle source 10 is, for example, a thermoelectron type charged particle source, and includes a cathode electrode 101 and an anode electrode 102. The cathode electrode 101 is formed from LaB₆ or BaO/W (dispenser cathode). The heating mechanism 103 formed from a heater heats, for example, the cathode electrode 101. The voltage applying unit 104 applies a predetermined voltage to each of the cathode electrode 101 and the anode electrode 102. This causes the charged particle source 10 to generate a charged particle beam.

The charged particle beam extracted from the cathode electrode 101 by the anode electrode 102 is converted into a parallel charged particle beam by the collimator lens 105 and enters the aperture array 106. The condenser lens array 107 condenses the charged particle beams divided (split) by the aperture array 106. The aperture array 108 further divides the charged particle beam into many charged particle beams. The charged particle beams divided by the aperture array 108 are formed into images on the blanker array 109.

The condenser lens array 107 includes, for example, three porous electrodes. Of the three electrodes, the upper and lower electrodes are grounded, and a negative voltage is applied to only the intermediate electrode. That is, the condenser lens array 107 is formed from an Einzel type electrostatic lens. In addition, the aperture array 108 is disposed at the pupil plane position of the condenser lens array 107 (the front-side focal plane position of the condenser lens array 107), and an NA (convergence half angle) is defined by the aperture array 108.

The blanker array 109 includes a plurality of deflecting electrodes (deflectors) and performs blanking operation based on the blanking signal generated by a blanking signal generation unit including a drawing pattern generation circuit, bitmap conversion circuit, and blanking command circuit. Blanking operation is the operation of controlling irradiation (ON) and non-irradiation (OFF) of a charged particle beam to a substrate 113 in accordance with a drawing pattern. When irradiating with a charged particle beam, the charged particle beam from the aperture array 108 passes through the opening of the blanking aperture 111 without applying any voltage to the deflecting electrode of the blanker array 109 (that is, without deflecting the charged particle beam). When not irradiating with a charged particle beam, the blanking aperture 111 shuts off the charged particle beam from the aperture array 108 by applying a voltage to the deflecting electrode of the blanker array 109 (that is, deflecting the charged particle beam).

The condenser lens array 112 is an objective lens whose reduction magnification is set to about ×100 in this embodiment. Therefore, a charged particle beam on the blanker array 109 (intermediate imaging plane) is reduced to 1/100 on the substrate 113. For example, a charged particle beam having a spot diameter of 2 μm in terms of FWHM (Full Width at Half Maximum) on the blanker array 109 becomes a charged particle beam having a spot diameter of about 20 nm in terms of FWHM on the substrate 113.

The deflector 114 is formed from electrodes opposing each other (opposite electrodes) and deflects (scans) the charged particle beam condensed on the substrate 113 by the condenser lens array 112. In this embodiment, the deflector 114 is formed from four counterelectrodes to perform deflection in two steps in the X-axis direction and the Y-axis direction.

The substrate stage 115 holds and moves the substrate 113. When drawing a pattern, the apparatus continuously moves the substrate stage 115 holding the substrate 113 in the X-axis direction and deflects a charged particle beam on the substrate 113 in the Y-axis direction by using the deflector 114 with reference to a real-time length measurement result (the position of the substrate stage 115) obtained by a laser interferometer. In this case, the blanker array 109 controls irradiation and non-irradiation of a charged particle beam onto the substrate 113 in accordance with a drawing pattern. With this operation, the apparatus draws a pattern on the substrate 113.

In this embodiment, the charged particle optical system forming the drawing apparatus 100 is roughly constituted by a first charged particle optical system FCS including the charged particle source 10 and a second charged particle optical system SCS including the aperture array 106.

The first charged particle optical system FCS is accommodated in the first chamber 501 defining a first space 301. The first chamber 501 is provided with the vacuum pump mechanism 116 and can maintain the first space 301 in a high vacuum state. In this embodiment, the first charged particle optical system FCS has rotational symmetry. Therefore, the electric field formed from the potential distribution of the cathode electrode 101 and anode electrode 102 is a distribution having rotational symmetry, and the central axis of the electric field having rotational symmetry coincides with the optical axis (axis) of the first charged particle optical system FCS.

The second charged particle optical system SCS is accommodated in the second chamber 502 defining a second space 302. The second chamber 502 is provided with the vacuum pump mechanism 117 and can maintain the second space 302 in a high vacuum state. Like the first charged particle optical system FCS, the second charged particle optical system SCS has rotational symmetry, and the central axis of such a rotational symmetrical shape coincides with the optical axis (axis) of the second charged particle optical system SCS.

In this embodiment, the third chamber 503 defining a third space 303 is disposed between the first space 301 and the second space 302. The third chamber 503 is provided with the vacuum pump mechanism 118 and can maintain the third space 303 in a high vacuum state.

The third space 303 defined by the third chamber 503 accommodates the movable detector 307 including a detection surface 307a which detects a charged particle beam and detects the position of the charged particle beam emerging from the first charged particle optical system FCS on the detection surface 307a. The detector 307 is formed from, for example, a CCD sensor or CMOS sensor having a two- or one-dimensional array of photo-electric conversion elements and configured to be moved by the moving unit 308. Consider a case in which the positional relationship between the first charged particle optical system FCS and the second charged particle optical system SCS is regulated. In this case, the moving unit 308 moves the detector 307 so as to place the detector 307 on the path (optical path) of a charged particle beam between the first charged particle optical system FCS and the second charged particle optical system SCS. When drawing on the substrate 113, the moving unit 308 moves the detector 307 so as to remove (retract) from the detector 307 from the path between the first charged particle optical system FCS and the second charged particle optical system SCS.

The drawing apparatus 100 is provided with a valve mechanism 304 (gate valve mechanism or gate mechanism) for separating (partitioning) the first space 301 and the third space 303 and a valve mechanism 305 for separating the second space 302 and the third space 303. In this embodiment, the valve mechanism 304 is provided in the first chamber 501, and the valve mechanism 305 is provided in the third chamber 503. However, the present invention is not limited to this. For example, the valve mechanism 304 may be provided in the third chamber 503, and the valve mechanism 305 may be provided in the second chamber 502.

AS shown in FIG. 2, the first chamber 501 can be detachably attached to the third chamber 503 while the vacuum pump mechanism 116 and the valve mechanism 304 maintain the first space 301 in a high vacuum state. FIG. 2 shows a state in which the first chamber 501 is detached from the third chamber 503. While the first chamber 501 is detached from the third chamber 503, the second chamber 502 can be maintained in a high vacuum state without making the vacuum pump mechanism 117 and the valve mechanism 305 release the second space 302 to the atmosphere. With this arrangement, this embodiment can easily and quickly exchange the charged particle source 10 included in the first charged particle optical system FCS.

The regulation unit 119 regulates the relative position between the first charged particle optical system FCS and the second charged particle optical system SCS based on an output from the detector 307. The regulation unit 119 is formed from a mechanism for regulating the position of a charged particle beam emerging from the first charged particle optical system FCS, that is, the position of the optical axis of the first charged particle optical system FCS. This mechanism includes, for example, at least one of a mechanism for finely regulating the mount position of the first charged particle optical system FCS relative to the second charged particle optical system SCS or a mechanism for finely regulating the position of the charged particle source 10 in the first charged particle optical system FCS. More specifically, each of these mechanisms can be formed from at least one of an actuator which moves the overall first charged particle optical system FCS or the first chamber 501, or an actuator which moves the charged particle source 10.

The control unit 120 includes a CPU and a memory and controls the whole (operation) of the drawing apparatus 100. In this embodiment, the control unit 120 functions as a calculation unit which calculates the relative position between the first charged particle optical system FCS and the second charged particle optical system SCS based on an output from the detector 307 (the position of a charged particle beam emerging from the first charged particle optical system FCS). For example, the control unit 120 calculates the position of the optical axis of the first charged particle optical system FCS relative to the optical axis of the second charged particle optical system SCS as the relative position between the first charged particle optical system FCS and the second charged particle optical system SCS. In addition, the control unit 120 functions as a processing unit which performs the exchange processing of exchanging the charged particle source 10 included in the first charged particle optical system FCS with a new charged particle source.

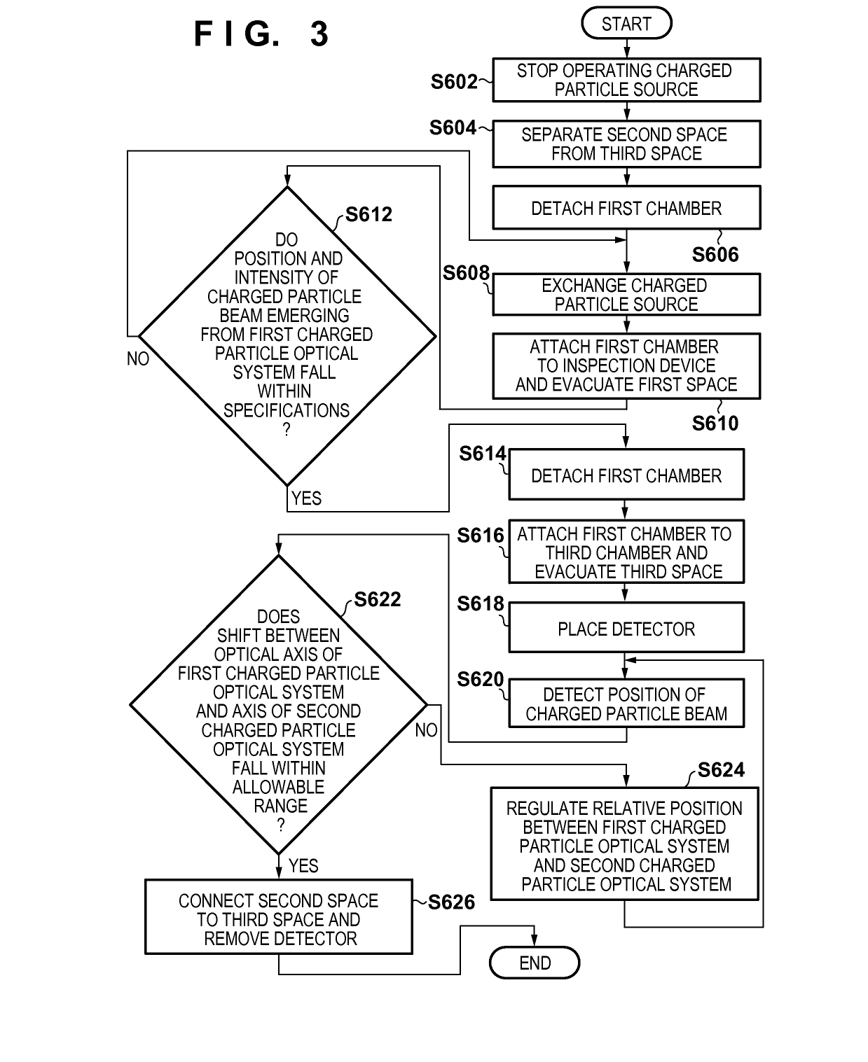

Exchange processing for the charged particle source 10 in the drawing apparatus 100 will be described with reference to FIG. 3. As described above, the control unit 120 performs this exchange processing by comprehensively controlling the respective units of the drawing apparatus 100. In this embodiment, when exchanging the charged particle source 10, the apparatus detaches (separates) the first chamber 501 from the third chamber 503 and exchanges it with a new charged particle source. The apparatus then attaches the first chamber 501 to the third chamber 503. Upon attaching the first chamber 501 to the third chamber 503, it is necessary to regulate the relative position between the first charged particle optical system FCS and the second charged particle optical system SCS so as to match the optical axis of the first charged particle optical system FCS with the optical axis of the second charged particle optical system SCS.

In step S602, the operation of the charged particle source 10 is stopped. More specifically, the heating mechanism 103 stops heating the cathode electrode 101, and the voltage applying unit 104 stops applying voltages to the cathode electrode 101 and the anode electrode 102.

In step S604, the valve mechanism 305 separates the second space 302 and the third space 303. In this case, the apparatus keeps operating the vacuum pump mechanism 117 to maintain the second space 302 in a high vacuum state.

In step S606, the apparatus stops operating the vacuum pump mechanisms 116 and 118, releases the first space 301, that is, the first chamber 501, to the atmosphere, and detaches the first chamber 501 from the third chamber 503.

In step S608, the charged particle source 10 is exchanged. More specifically, the apparatus unloads the charged particle source 10 from the first chamber 501 and loads the new charged particle source 10 into the first chamber 501. The apparatus mounts the new charged particle source 10 at a predetermined position in the first charged particle optical system FCS.

In step S610, the apparatus attaches an optical mechanism for inspection (maintenance) (to be referred to as an “inspection device” hereinafter) to the first chamber 501, and operates the vacuum pump mechanism 116 to set the first space 301 in a high vacuum state (evacuate the first space 301). When setting the first space 301 in a high vacuum state, the apparatus connects the first space 301 to the inspection device through the valve mechanism 304.

In step S612, maintenance for the charged particle source 10 is performed and the control unit 120 determines whether the position and intensity of a charged particle beam emerging from the first charged particle optical system FCS (charged particle source 10) fall within the specifications. In this case, maintenance for the charged particle source 10 includes bakeout and conditioning processing for the cathode electrode 101 and the anode electrode 102. If the position and intensity of a charged particle beam emerging from the first charged particle optical system FCS do not fall within the specifications, the process shifts to step S608 to exchange the charged particle source 10 again. If the position and intensity of a charged particle beam emerging from the first charged particle optical system FCS fall within the specifications, the process shifts to step S614.

In step S614, the apparatus detaches the first chamber 501 from the inspection device. More specifically, the valve mechanism 304 separates the first space 301 from the outside (inspection device). The apparatus then detaches the first chamber 501 from the inspection device while keeping operating the vacuum pump mechanism 116 and maintaining the first space 301 in a high vacuum state.

In step S616, the apparatus attaches the first chamber 501 to the third chamber 503 and operates the vacuum pump mechanism 118 to set the third space 303 in a high vacuum state (evacuate the third space 303). When the third space 303 is set in a high vacuum state, the first space 301 is connected to the third space 303 through the valve mechanism 304.

In step S618, the moving unit 308 places the detector 307 in the third space 303, that is, in the path between the first charged particle optical system FCS and the second charged particle optical system SCS. More specifically, the detector 307 is placed such that the detection surface 307a is positioned near the optical axis of the first charged particle optical system FCS (for example, the position at which the optical axis should exist).

In step S620, the charged particle source 10 generates a charged particle beam, and the detector 307 detects the position of a charged particle beam (on the detection surface 307a) emerging from the first charged particle optical system FCS. When performing this detection, the voltage applying unit 104 applies, to the charged particle source 10, a voltage different from the voltage applied to the charged particle source 10 to draw on the substrate 113, so as to condense a charged particle beam emerging from the first charged particle optical system FCS on the detection surface 307a of the detector 307.

In step S622, the control unit 120 determines, based on the position of the charged particle beam detected in step S620, whether the shift between the optical axis of the first charged particle optical system FCS and the optical axis of the second charged particle optical system SCS falls within an allowable range. More specifically, based on the position of the charged particle beam detected in step S620, the control unit 120 obtains the relative position between the first charged particle optical system FCS and the second charged particle optical system SCS, more specifically, the positional shift between the optical axis of the second charged particle optical system SCS and the optical axis of the first charged particle optical system FCS in this embodiment. The control unit 120 then determines whether the shift falls within the allowable range. Assume that the position of the optical axis of the second charged particle optical system SCS is known in advance (calibrated). Note that the relative position (positional shift) is not limited to the above positional shift between the optical axes and may be the positional shift of the first charged particle optical system FCS in the optical axis direction or may include both of them. It is possible to obtain the positional shift of the first charged particle optical system FCS in the optical axis direction by detecting the size (diameter) of a charged particle beam emerging from the first charged particle optical system FCS using the detector 307.

If the shift between the optical axis of the first charged particle optical system FCS and the optical axis of the second charged particle optical system SCS does not fall within the allowable range, the process shifts to step S624. If the shift between the optical axis of the first charged particle optical system FCS and the optical axis of the second charged particle optical system SCS falls within the allowable range, the process shifts to step S626.

In step S624, the regulation unit 119 regulates the relative position between the first charged particle optical system FCS and the second charged particle optical system SCS so as to match the optical axis of the first charged particle optical system FCS with the optical axis of the second charged particle optical system SCS. The regulation unit 119 performs such regulation based on the shift obtained in step S622. When the regulation unit 119 regulates the relative position between the first charged particle optical system FCS and the second charged particle optical system SCS, the process shifts to step S620 to detect the position of a charged particle beam emerging from the first charged particle optical system FCS. In this embodiment, the regulation unit 119 regulates the relative position between the first charged particle optical system FCS and the second charged particle optical system SCS while the first chamber 501 is attached to the third chamber 503. However, the regulation unit 119 may regulate the first charged particle optical system FCS while the first chamber 501 is detached from the third chamber 503.

In step S626, while connecting the second space 302 to the third space 303 through the valve mechanism 305, the apparatus removes the detector 307 from the path between the first charged particle optical system FCS and the second charged particle optical system SCS by using the moving unit 308, and terminates exchange processing for the charged particle source 10.

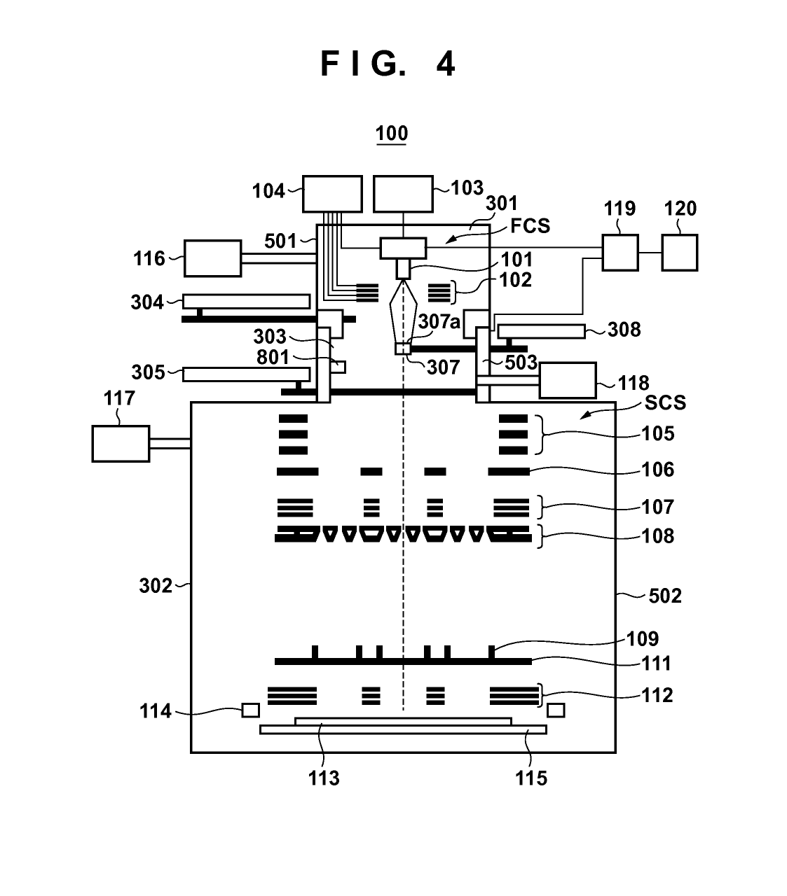

FIG. 4 is a schematic view showing a state in which the position of a charged particle beam emerging from the first charged particle optical system FCS is detected in step S620. As described above, in step S620, a voltage different from the voltage applied to draw on the substrate 113 is applied to the anode electrode 102 to condense a charged particle beam emerging from the first charged particle optical system FCS on the detection surface 307a of the detector 307. Therefore, disposing the detector 307 at a position near the optical axis of the first charged particle optical system FCS can detect the position of a charged particle beam emerging from the first charged particle optical system FCS.

As described above, the drawing apparatus 100 can detect the position of a charged particle beam emerging from the first charged particle optical system FCS (that is, align the optical axis of the charged particle source 10) on the apparatus. While exchanging or maintaining the charged particle source 10, the drawing apparatus 100 can match the optical axis of the first charged particle optical system FCS with the optical axis of the second charged particle optical system SCS in a short period of time (within an allowable range). The drawing apparatus 100 shortens the down time in exchange or maintenance of the charged particle source 10, and is advantageous in productivity.

A removing unit 801 for removing contaminants can also be disposed in the third space 303 defined by the third chamber 503. In this case, upon attaching the first chamber 501 to the third chamber 503, the apparatus may execute the removal of contaminants by using the removing unit 801 before connecting the first space 301 to the third space 303 and connecting the second space 302 to the third space 303. This makes it possible to effectively remove contaminants existing in the third space 303. It is however possible to perform the removal of contaminants by using the removing unit 801 after connecting the first space 301 to the third space 303 and connecting the second space 302 to the third space 303. This makes it possible to remove contaminants existing in the first space 301 and the second space 302 in addition to the third space 303. The removing unit 801 can be formed from, for example, an ion pump or ion getter.

The position at which the detector 307 is disposed is not limited to the position shown in FIG. 4 and may be a position after the first charged particle optical system FCS and before the aperture array 106. Likewise, the positions at which the valve mechanisms 304 and 305 are disposed are not limited to those shown in FIG. 1 and may be positions after the first charged particle optical system FCS and before the aperture array 106.

This embodiment provides the vacuum pump mechanisms 116, 117, and 118 in the first space 301, the second space 302, and the third space 303, respectively. The number of vacuum pump mechanisms may be decreased by attaching opening/closing mechanisms to the vacuum exhaust path connected to one vacuum pump mechanism. Surplus vacuum pump mechanisms may be provided. Note that this embodiment can execute positioning of the first charged particle optical system FCS at an arbitrary timing instead of the exchange time of the charged particle source 10. This positioning may be executed when the shift between the axis of the first charged particle optical system FCS and the axis of the second charged particle optical system SCS falls outside a predetermined allowable range or at predetermined time intervals.

Alternatively, the drawing apparatus 100 may include a spare chamber as a spare of the first chamber 501. This makes it possible to perform bakeout or conditioning processing for the cathode electrode 101 and the anode electrode 102 in a spare chamber, thus further shortening the time required for exchange processing for the charged particle source 10.

A method of manufacturing an article according to an embodiment of the present invention is suitable for manufacturing an article such as a microdevice such as a semiconductor device or an element having a microstructure. This manufacturing method can include the step of forming a latent image pattern on a photosensitizing agent applied on a substrate by using the drawing apparatus 100 (the step of performing drawing on a substrate) and the step of developing the substrate on which the latent image pattern has been formed in the preceding step (the step of developing the substrate on which drawing has been performed). The manufacturing method can further include other known steps (oxidation, film formation, deposition, doping, planarization, etching, resist removal, dicing, bonding, packaging, and the like). The method of manufacturing an article according to this embodiment is superior to the conventional method in at least one of the performance of an article, quality, productivity, and production cost.

In addition, the present invention can be applied to not only a drawing apparatus but also an irradiation apparatus which irradiates an object with a charged particle beam, such as a microscope using a charged particle beam (electron beam).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-229244 filed on Oct. 16, 2012, which is hereby incorporated by reference herein in its entirety.

1. An irradiation apparatus which irradiates an object with a charged particle beam, the apparatus comprising:
a first charged particle optical system including a charged particle source;
a second charged particle optical system into which a charged particle beam is incident from the first charged particle optical system;
a detector configured to be moved and to detect a charged particle beam from the first charged particle optical system; and
a regulator configured to regulate relative positions between the first charged particle optical system and the second charged particle optical system based on an output from the detector disposed between the first charged particle optical system and the second charged particle optical system.

2. The apparatus according to claim 1, wherein the first charged particle optical system is configured, if the detector detects a charged particle beam from the first charged particle optical system, to condense the charged particle beam onto a detection surface of the detector.

3. The apparatus according to claim 1, wherein the regulator is configured to obtain a deviation of an axis of the first charged particle optical system relative to an axis of the second charged particle optical system based on an output from the detector, and to regulate the relative positions such that the axis of the first charged particle optical system and the axis of the second charged particle optical system are aligned with each other based on the deviation.

4. The apparatus according to claim 1, further comprising:
a first chamber configured to accommodate the first charged particle optical system;
a second chamber configured to accommodate the second charged particle optical system; and
a third chamber provided between the first chamber and the second chamber,
wherein the third chamber is provided with the detector.

5. The apparatus according to claim 4, further comprising an exchanger configured to detach the first chamber from the third chamber, and to perform exchange of the charged particle source with a new charged particle source,
wherein the regulator is configured to regulate the relative positions if the exchanger performs the exchange.

6. The apparatus according to claim 4, further comprising a removing device provided with the third chamber and configured to remove a contaminant.

7. The apparatus according to claim 6, further comprising a partitioning mechanism configured to partition the second chamber from the third chamber,
wherein the removing device is configured to remove the contaminant with the second chamber partitioned from the third chamber by the partitioning mechanism.

8. The apparatus according to claim 1, wherein the second charged particle optical system includes an aperture array member configured to divide a charged particle beam from the first charged particle optical system into a plurality of charged particle beams.

9. A drawing apparatus which performs drawing on a substrate with a charged particle beam, the apparatus comprising an irradiation apparatus, which irradiates an object with a charged particle beam, the apparatus comprising:
a first charged particle optical system including a charged particle source;
a second charged particle optical system into which a charged particle beam is incident from the first charged particle optical system;
a detector configured to be moved and to detect a charged particle beam from the first charged particle optical system; and
a regulator configured to regulate relative positions between the first charged particle optical system and the second charged particle optical system based on an output from the detector disposed between the first charged particle optical system and the second charged particle optical system,
wherein the irradiation apparatus is configured to irradiate a substrate with the charged particle beam.

10. A method of manufacturing an article, the method comprising:
performing drawing on a substrate using a drawing apparatus;
developing the substrate on which the drawing has been performed; and
processing the developed substrate to manufacture the article,
wherein the drawing apparatus performs the drawing on the substrate with a charged particle beam, the drawing apparatus including:
an irradiation apparatus which irradiates the substrate with the charged particle beam, the irradiation apparatus including:
a first charged particle optical system including a charged particle source;
a second charged particle optical system into which a charged particle beam is incident from the first charged particle optical system;
a detector configured to be moved and to detect a charged particle beam from the first charged particle optical system; and
a regulator configured to regulate relative positions between the first charged particle optical system and the second charged particle optical system based on an output from the detector disposed between the first charged particle optical system and the second charged particle optical system.
